(19) United States
(12) Patent Application Publication
(10) Pub. No.: US 2001/0004114 A1
(43) Pub. Date: Jun. 21, 2001

(54) Semiconductor light emitter and method for fabricating the same

(76) Inventor: Masaaki Yuri, Osaka (JP)

Correspondence Address: Eric J. Robinson, Nixon Peabody LLP, 8180 Greensboro Drive, Suite 800, McLean, VA, 22102, US

(21) Appl. No.: 09/735,793

(22) Filed: Dec. 14, 2000

(30) Foreign Application Priority Data
Dec. 15, 1999 (JP) 11-355435

(51) Int. Cl. H01L 33/00; H01L 21/00

(52) U.S. Cl. 257/94; 438/22

(57) ABSTRACT

A semiconductor light emitter includes: a first semiconductor layer formed over a substrate; a second semiconductor layer formed over the first layer; and a third semiconductor layer formed over the second layer. Bandgaps of the first and third layers are greater than a bandgap of the second layer. A high-quantum-level region is defined around an edge of the second layer. A first quantum level is higher in the high-quantum-level region than in the other region of the second layer.

### BACKGROUND OF THE INVENTION

The present invention relates to a semiconductor light emitter with a quantum well structure like a semiconductor laser diode or light-emitting diode.

In recent years, research and development has been vigorously carried on to realize a quantum well device with a novel function by making the bandgap in part of the active layer of a semiconductor light emitter different from the remaining part thereof. The bandgap can be made different by changing the thickness or composition of a selected part of the active layer.

For example, currently available red-light-emitting semiconductor laser diodes should have their catastrophic optical damage (COD) minimized to obtain as high an optical output power as 30 mW or more. Thus, the technique of controlling the bandgap within a plane of the active layer is applied thereto for that purpose. As used herein, the COD refers to a phenomenon by which the crystallinity of an emitter rapidly deteriorates at its facets when the emitter increases its optical output power. This phenomenon is caused because the radiation with that high power is absorbed into the emitter around the facets and the crystals, making up the facets, are molten due to the heat generated.

To avoid this COD phenomenon, a semiconductor laser diode with a so-called “facet window structure” was proposed as disclosed in Japanese Laid-Open Publication No. 58-500681. According to this technique, the light-emitting facets are intentionally disordered by diffusing the dopant introduced so that the quantum well structure will have its bandgap increased around the facets. This technique will be herein called a “first prior art example” for convenience sake.

Also, another method of preventing the radiation, emitted from the active layer of a semiconductor laser diode, from being absorbed into the diode around its facets was disclosed in Japanese Laid-Open Publication No. 6-21568. According to this technique, portions of the active layer near the light-emitting facets are removed and a semiconductor layer, having a bandgap greater than that of the active layer, is formed instead in those portions. This technique will be herein called a “second prior art example” for convenience sake.

Hereinafter, a semiconductor laser diode according to the first prior art example will be described with reference to the accompanying drawings.

FIG. 13 illustrates a cross-sectional structure of the resonant cavity of a known semiconductor laser diode with the “facet window structure”. The cross section illustrated in FIG. 13 is taken in the direction in which resonance occurs in the resonant cavity (which will be herein called a “resonance direction”).

As shown in FIG. 13, first cladding layer 102, first optical guide layer 103, active layer 104, second optical guide layer 105, second cladding layer 106, current blocking layer (not shown) and contact layer 108 are stacked in this order on an n-GaAs substrate 101. The first cladding layer 102 is made of n-Al_{0.5}Ga_{0.5}As and has a thickness of 1.5 μm. The first optical guide layer 103 is made of undoped Al_{0.3}Ga_{0.7}As and has a thickness of 20 nm. The active layer 104 is made of undoped Al_{0.1}Ga_{0.9}As and has a thickness of 9 nm. The second optical guide layer 105 is made of undoped Al_{0.3}Ga_{0.7}As and has a thickness of 20 nm. The second cladding layer 106 is made of p-al_{0.5}Ga_{0.5}As and includes a waveguide with ridges extending in the resonance direction. The thickness of the second cladding layer 106 at the top of the ridges is 1.5 μm, while the thickness thereof at the bottom of the ridges is 0.15 μm. The current blocking layer is made of n-GaAs and has a thickness of 1.35 μm. And the contact layer 108 is made of p-GaAs and has a thickness of 2 μm.

Around the facets of the resonant cavity, zinc (Zn) diffused regions 109a, extending from the contact layer 108 through the active layer 104, are defined by thermally diffusing Zn. In the following description, a region 109b located between the Zn-diffused regions 109a will be referred to as a non-Zn-diffused region 109b.

FIGS. 14A and 14B illustrate the distributions of bandgaps in the non-Zn-diffused region 109b and Zn-diffused regions 109a in the depth direction, respectively.

As shown in FIG. 14B, the Al mole fraction of the active layer 104, which was 0.1 originally, increases in the Zn-diffused regions 109a, because interdiffusion is caused between the Zn atoms diffused and Ga or Al atoms. Accordingly, in the Zn-diffused regions 109a, the wavelength at the peak of absorption becomes shorter than the oscillation wavelength of the laser diode, which is determined by the active layer in the non-Zn-diffused region 109b. As a result, the Zn-diffused regions 109a become substantially transparent to the radiation with the oscillation wavelength, and the amount of light absorbed into the facets of the resonant cavity can be reduced.

In the semiconductor laser diode of the second prior art example, recombined radiation, created in the active layer, is guided to the optical guide layers and then emitted from the facets. In this case, the active layer, including the facets, is entirely covered with the first cladding layer and is not exposed. Accordingly, the COD is unlikely to be caused at the facets of the resonant cavity.

However, the semiconductor laser diode of the first prior art example has the following drawbacks.

Firstly, the crystals in the active layer 104 and the first and second optical guide layers 103 and 105 are intentionally disordered in the laser diode. Accordingly, the active layer 104 has its crystallinity deteriorated and is more likely to cause crystal imperfections, thus decreasing the reliability of the laser diode.

Secondly, the diffused Zn atoms remain interstitially among the atoms of semiconductor crystals that make up the active layer 104. Accordingly, if the laser diode is operated for a long time, then the temperature of the diode goes on rising to further diffuse the Zn atoms. As a result, the performance of the laser diode noticeably deteriorates with time.

Thirdly, if Zn is doped at a high level, then the active layer 104 itself absorbs a greater number of free carriers more easily. Consequently, the threshold current rises and the slope efficiency (which is a variation in optical output power against operating current) decreases.

In the semiconductor laser diode of the second prior art example, the active layer has been partially removed around the facets to form steps, on which the first cladding layer is formed through re-growth. Accordingly, the active layer might be damaged or the crystallinity might deteriorate around the interface between the active layer and the first cladding layer (particularly in an interface around the facets from which the laser radiation is emitted). As a result, the laser diode might have its reliability degraded. Furthermore, a degraded layer might be formed around the interface. In that case, the laser radiation is unintentionally absorbed into the facets and their surrounding regions to cause the COD phenomenon in the end.

### SUMMARY OF THE INVENTION

An object of the invention is suppressing the COD and deterioration in performance of a semiconductor light emitter with time by minimizing the degradation in crystallinity of the active layer and by considerably reducing the amount of light absorbed in the facets of the resonant cavity and surrounding regions.

To achieve this object, according to the present invention, the quantum energy level is set higher around the facets of the resonant cavity of a semiconductor light emitter than in the other region thereof.

Specifically, a first inventive semiconductor light emitter includes: a first semiconductor layer formed over a substrate; a second semiconductor layer formed over the first layer; and a third semiconductor layer formed over the second layer. Bandgaps of the first and third layers are greater than a bandgap of the second layer. A high-quantum-level region is defined around an edge of the second layer. In the high-quantum-level region, the first quantum level is higher than in the other region of the second layer.

In the first inventive light emitter, the bandgaps of the first and third layers are greater than that of the second layer. In addition, a high-quantum-level region is defined around an edge of the second layer. In the high-quantum-level region, the first quantum level is higher than in the other region of the second layer. Accordingly, an absorption coefficient considerably decreases at the edges of the second layer and the radiation emitted from the second layer is much less likely to be absorbed into the edges. As a result, the COD phenomenon can be suppressed and the deterioration in performance of the laser diode with time can be minimized.

In one embodiment of the present invention, parts of the first or third layer, which are located near the edges of the second layer, preferably have a bandgap greater than the other part of the first or third layer. In such an embodiment, the first quantum level can be increased just as intended at the edges of the second layer interposed between the first and third layers.

In another embodiment of the present invention, the first layer preferably has a pair of facets that extend substantially vertically to the principal surface of the substrate and that face each other, and at least one of these facets is preferably located in the high-quantum-level region. In such an embodiment, if the pair of facets is used as the facets of the resonant cavity, then the COD can be suppressed at the facets of the resonant cavity just as intended.

In still another embodiment, each said high-quantum-level region is preferably defined to extend from an associated facet of the second layer inward over a predetermined distance. Then, the second layer can create radiation at a desired wavelength.

In yet another embodiment, the first or third layer preferably has a thickness of 0.5 nm through 20 nm.

In yet another embodiment, the first or third layer is preferably made of a semiconductor that reacts with oxygen atoms more easily than the second layer does. And oxygen atoms have preferably been introduced into edges of the first or third layer to a level higher than the other part of the first or third layer so that a bandgap at the edges of the first or third layer is greater than that in the other part of the first or third layer. In such an embodiment, the first quantum level can be increased just as intended at the edges of the second layer interposed between the first and third layers. In addition, the second layer is much less likely to be affected by the oxygen atoms introduced.

In yet another embodiment, the first and third layers may be made of AlGaAs, and the second layer may be made of: AlGaAs that has an Al mole fraction smaller than that of AlGaAs for the first and third layers; InGaAs; or GaAs.

In an alternative embodiment, the first and third layers may be made of AlGaInP, and the second layer may be made of: AlGaInP that has an Al mole fraction smaller than that of AlGaInP for the first and third layers; InGaP; or GaAs.

Whether the first and third layers are made of AlGaAs or AlGaInP, the Al mole fraction in the second layer is preferably 0.3 or less.

As another alternative, the first and third layers may be made of B_{K}Al_{y}Ga_{1-x-y-z}In_{z}N, where 0≦x≦1, 0≦y≦1, 0≦z≦1 and 0≦x+y+z≦1, and the second layer may be made of: BₓAl_{y}Ga_{1-x-y-z}In_{z}N, where 0≦x≦1, 0≦y≦1, 0≦z≦1 and 0≦x+y+z≦1 and which has an Al mole fraction smaller than that of BₓAl_{y}Ga_{1-x-y-z}In_{z}N for the first and third layers; InGaN; or GaN.

A second inventive semiconductor light emitter includes: a first semiconductor layer formed over a substrate; a second semiconductor layer formed over the first layer; and a third semiconductor layer formed over the second layer. The first or third layer has a bandgap greater than that of the second layer and is made of a semiconductor that reacts with oxygen atoms more easily than the second layer does. And oxygen atoms have been introduced into edges of the first or third layer to a level higher than the other part of the first or third layer so that a bandgap at the edges of the first or third layer is greater than that in the other part of the first or third layer.

In the second semiconductor light emitter, where the second layer has a quantum well structure, the first quantum level increases at the edges of the second layer interposed between the first and third layers. Accordingly, if the edges of the second layer are used as the facets of the resonant cavity, the absorption coefficient considerably decreases at the facets and the emission from the second layer is much less likely to be absorbed into the facets. As a result, the COD can be suppressed and the deterioration in performance of the light emitter with time can be minimized.

Furthermore, the second layer is not easily affected by the oxygen atoms introduced and the edges of the first or third layer have been oxidized. Accordingly, current injected does not flow easily through the edges of the second layer. That is to say, the current injected is concentrated to the center of the second layer. As a result, where the light emitter is a surface-emitting laser diode, the resultant luminous efficacy increases greatly.

In one embodiment of the present invention, the second layer preferably includes a quantum well layer.

An inventive method for fabricating a semiconductor light emitter includes the steps of: a) stacking first, second and third semiconductor layers in this order over a substrate to obtain a multilayer structure including the first, second and third layers; and b) exposing at least one side face of the multilayer structure to an ambient containing oxygen atoms, thereby oxidizing a side face of the first or second layer.

According to the inventive method, the first or second inventive semiconductor light emitter can be fabricated just as originally designed without damaging the second semiconductor layer (that will be an active layer) at all.

In one embodiment of the present invention, the first and third layers preferably have a bandgap greater than that of the second layer.

In another embodiment of the present invention, the first or third layer is preferably made of a semiconductor that reacts with oxygen atoms more easily than the second layer does.

In still another embodiment, the step a) preferably includes the step of forming a quantum well layer in the second layer.

In yet another embodiment, the step b) preferably includes an annealing process in which water vapor is used as the ambient.

### BRIEF DESCRIPTION OF THE DRAWINGS

FIG. 1 is a cross-sectional view, taken in the resonance direction, illustrating a structure for a semiconductor laser diode according to a first embodiment of the present invention.

FIGS. 2A and 2B are band diagrams illustrating energy levels around a quantum well active layer of the semiconductor laser diode of the first embodiment:

FIG. 2A illustrates energy levels for part of the laser diode including a part with a low Al mole fraction; and

FIG. 2B illustrates energy levels for another part of the laser diode including a part with a high Al mole fraction.

FIG. 3 is a graph illustrating the spectra of radiation emitted from those parts with high and low Al fractions, respectively, of the quantum well active layer in the laser diode of the first embodiment.

FIGS. 4A through 4C are cross-sectional views illustrating respective process steps for fabricating the semiconductor laser diode of the first embodiment.

FIG. 5 is a graph illustrating the current-optical output power characteristics of semiconductor laser diodes according to the first embodiment and the first prior art example in comparison.

FIG. 6 is a graph illustrating results of a high-temperature continuity test that was carried out on semiconductor laser diodes according to the first embodiment and the first prior art example.

FIG. 7 is a cross-sectional view, taken in the resonance direction, illustrating a structure for a semiconductor laser diode according to a modified example of the first embodiment.

FIG. 8 is a cross-sectional view, taken in the resonance direction, illustrating a structure for a semiconductor laser diode according to a second embodiment of the present invention.

FIGS. 9A and 9B are cross-sectional views illustrating respective process steps for fabricating the semiconductor laser diode of the second embodiment.

FIG. 10 is a graph illustrating the current-optical output power characteristics of the semiconductor laser diodes of the first and second embodiments in comparison.

FIG. 11 is a cross-sectional view illustrating a structure for a light-emitting diode according to a third embodiment of the present invention.

FIG. 12 is a graph illustrating the current-emission intensity characteristics of light-emitting diodes according to the third embodiment and a prior art example in comparison.

FIG. 13 is a cross-sectional view, taken in the resonance direction, illustrating a structure for a semiconductor laser diode according to the first prior art example.

FIGS. 14A and 14B are band diagrams illustrating the distributions of bandgaps in a semiconductor laser diode of the first prior art example:

FIG. 14A illustrates energy levels for a non-Zn-diffused region; and

FIG. 14B illustrates energy levels for a Zn-diffused region.

### DESCRIPTION OF THE PREFERRED EMBODIMENTS

EMBODIMENT 1

Hereinafter, a first embodiment of the present invention will be described with reference to the accompanying drawings.

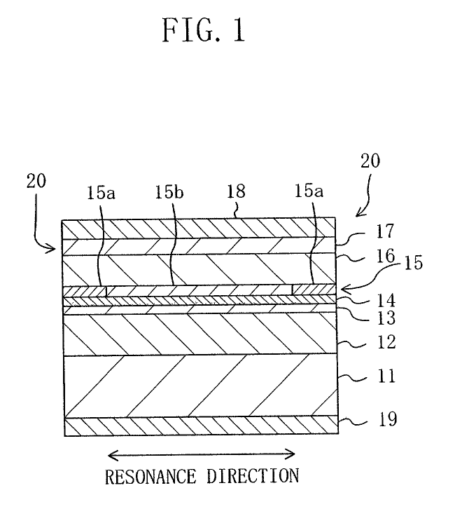

FIG. 1 illustrates a cross-sectional structure for a semiconductor laser diode according to the first embodiment. The cross section illustrated in FIG. 1 is taken in the resonance direction.

As shown in FIG. 1, an epitaxial structure is formed on a substrate 11 of n-GaAs, for example. The structure includes first cladding layer 12, first optical guide layer 13, quantum well active layer 14, second optical guide layer 15, second cladding layer 16 and contact layer 17 that have been stacked in this order. The first cladding layer 12 is made of n-Al_{0.5}Ga_{0.5}As and has a thickness of about 1.5 μm. The first optical guide layer 13 is made of undoped Al_{0.3}Ga_{0.7}As and has a thickness of about 20 nm. The active layer 14 is made of undoped GaAs and has a thickness of about 5 nm. The second optical guide layer 15 is made of undoped AlGaAs and has a thickness of about 20 nm. The second cladding layer 16 is made of p-Al_{0.5}Ga_{0.5}As. And the contact layer 17 is made of p-GaAs. It should be noted that the quantum well active layer 14 may also be made of AlGaAs with an Al mole fraction of 0.3 or less.

A p-side electrode 18 is formed on the contact layer 17 by stacking chromium (Cr), platinum (Pt) and gold (Au) layers, for example, in this order thereon. On the backside of the substrate 11, i.e., on the opposite side to the p-side electrode 18, an n-side electrode 19 is formed by stacking an alloy layer containing Au, germanium (Ge) and nickel (Ni), for example, and an Au layer in this order thereon.

The facets 20 of the epitaxial structure, which are located at both ends of the resonant cavity as defined in the resonance direction, are formed to be substantially vertical to the principal surface of the substrate 11 and to be parallel to each other.

The first embodiment is characterized in that part of the second optical guide layer 15, formed on the active layer 14, has an Al mole fraction different from that of the other parts thereof. And these two types of parts with mutually different Al mole fractions are adjacent to each other in the resonance direction. Specifically, parts of the second optical guide layer 15, extending from the facets 20 inward over a distance of about 10 μm each, are parts 15a with a high Al mole fraction of about 0.7 (which will be herein called “Al-rich parts”). The other part of the second optical guide layer 15 interposed between these parts 15a is a part 15b with a low Al mole fraction of about 0.3 (which will be herein called a “non-Al-rich part”). In this case, the second optical guide layer 15 functions as a barrier layer that confines electrons, holes and recombined radiation (i.e., recombined electron-hole pairs) in the quantum well active layer 14.

The second optical guide layer 15 includes the Al-rich parts 15a near both facets 20 of the resonant cavity. Thus, the bandgap of the Al-rich parts 15a is greater than that of the non-Al-rich part 15b. As a result, the first quantum level (i.e., the ground-state quantum level) in parts of the active layer 14 around the edges 20 of the resonant cavity becomes higher than that in the other part of the active layer 14 under the non-Al-rich part 15b.

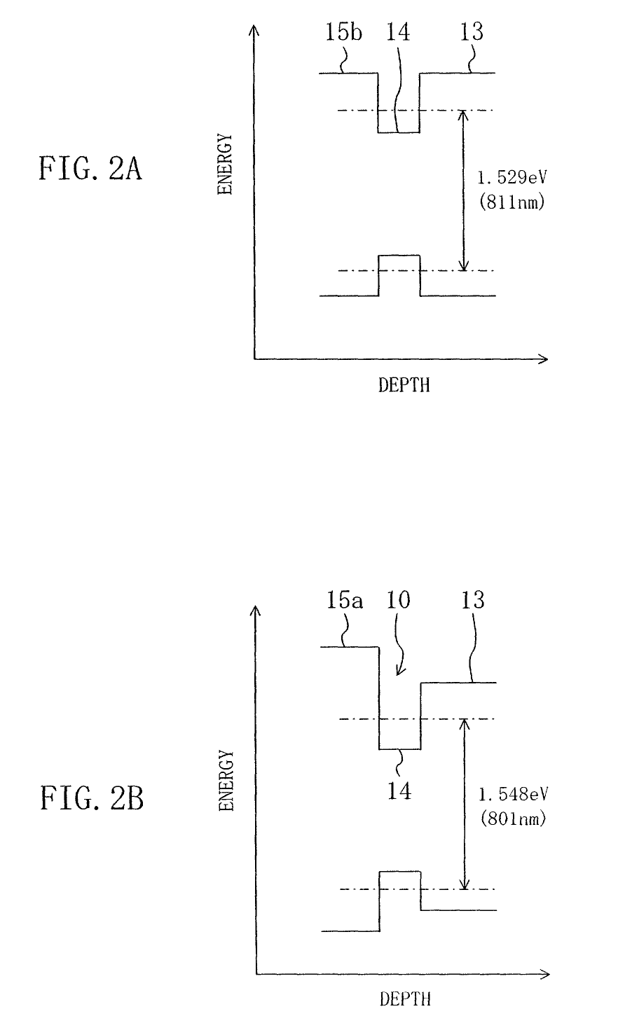

FIGS. 2A and 2B illustrate this quantum level shifting.

FIGS. 2A and 2B are band diagrams illustrating energy levels of the quantum well active layer 14 and its neighbors in the semiconductor laser diode of the first embodiment. FIG. 2A illustrates energy levels for the inner part of the resonant cavity including the non-Al-rich part 15b. FIG. 2B illustrates energy levels for the outer parts of the resonant cavity including the Al-rich parts 15a.

As shown in FIG. 2A, the quantum well has a horizontally symmetric structure in the region including the non-Al-rich part 15b. In this case, the energy required for electrons and holes to make transitions between the first quantum levels is 1.529 eV, which is equivalent to an oscillation wavelength of 811 nm for laser radiation.

On the other hand, the quantum well shown in FIG. 2B has an asymmetric structure in the regions including the Al-rich parts 15a located around the facets 20 of the resonant cavity. In this quantum well structure, the bandgap of the Al-rich part 15a is greater than that of the first optical guide layer 13. In this case, the energy required for transition between the first quantum levels is 1.548 eV, which is equivalent to an oscillation wavelength of 801 nm for laser radiation. In this manner, high-quantum-level regions 10 have been created because the first quantum level has risen to a higher energy level around the facets 20 of the resonant cavity.

Next, the emission spectra of the Al-rich and non-Al-rich parts 15a and 15b will be analyzed.

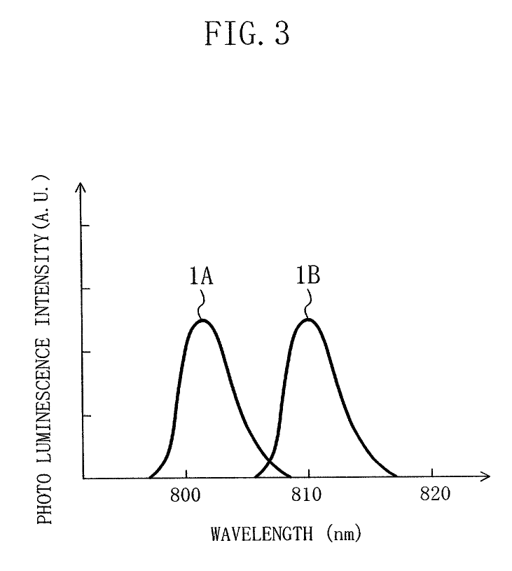

FIG. 3 illustrates the spectra of radiation emitted from respective parts of the quantum well active layer 14 under the Al-rich and non-Al-rich parts 15a and 15b, respectively, in the laser diode of the first embodiment. The spectra illustrated in FIG. 3 were measured by a photoluminescence spectroscopy. In FIG. 3, the abscissa indicates the wavelength, while the ordinate indicates the photoluminescence intensity at an arbitrary unit.

As shown in FIG. 3, the peak of the emission spectrum 1A corresponding to the Al-rich-parts 15a has shifted (i.e., decreased) from that of the emission spectrum 1B corresponding to the non-Al-rich part 15b by about 10 nm.

In this manner, those parts of the quantum well active layer 14, which are located under the Al-rich parts 15a, have their absorption coefficient decreased considerably. That is to say, the laser radiation, created in the active layer 14, is much less likely to be absorbed into the resonant cavity around the facets 20 thereof, thus suppressing the COD phenomenon. As a result, the semiconductor laser diode can have its threshold current density decreased and have its slope efficiency and maximum optical output power both increased.

According to the first embodiment, the Al-rich and non-Al-rich parts 15a and 15b are defined along a plane of the second optical guide layer 15 and the quantum well active layer 14, located under the second optical guide layer 15, is not altered in any way. Thus, no damage is done on the active layer 14. That is to say, since the crystallinity of the active layer 14 does not deteriorate, the loss does not increase or the reliability does not degrade, either.

In the first embodiment, the Al-rich and non-Al-rich parts 15a and 15b are formed in the second optical guide layer 15. Alternatively, these parts may be defined in the first optical guide layer 13 located under the active layer 14. And if necessary, these parts may be provided for both the first and second optical guide layers 13 and 15.

Furthermore, the quantum well active layer 14 is made of GaAs in the foregoing embodiment. Optionally, the active layer 14 may contain aluminum so long as the Al mole fraction of the active layer 14 is smaller than that of the first or second optical guide layer 13 or 15.

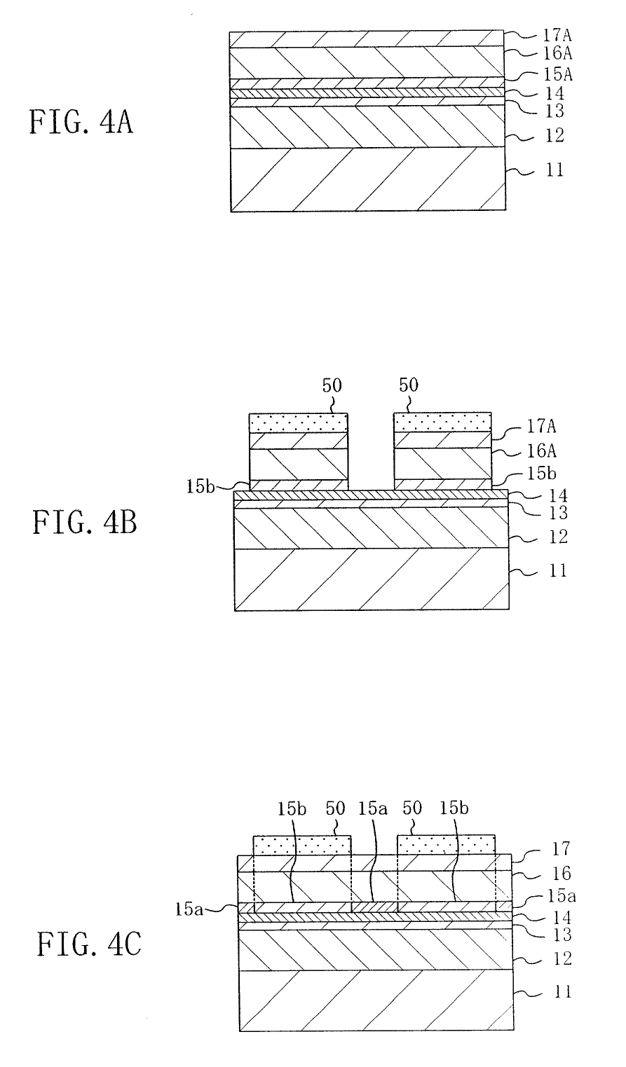

Hereinafter, a method for fabricating a semiconductor laser diode with such a structure will be described with reference to FIGS. 4A through 4C.

FIGS. 4A through 4C illustrate cross-sectional structures corresponding to respective process steps for fabricating the semiconductor laser diode of the first embodiment.

First, as shown in FIG. 4A, the first cladding layer 12, first optical guide layer 13, quantum well active layer 14, second optical guide layer prototype 15A, second cladding layer prototype 16A and contact layer prototype 17A are formed in this order on the n-GaAs substrate 11 by a metalorganic vapor phase epitaxy (MOVPE) process, for example. In this process step, the second optical guide layer prototype 15A is made of p-Al_{0.3}Ga_{0.7}As. In this manner, an epitaxial substrate is prepared.

Next, as shown in FIG. 4B, a mask pattern 50 having an opening with a width of about 20 μm as measured in the resonance direction is defined by photolithography on the epitaxial substrate. And the substrate is dry-etched using the pattern 50 as a mask until the active layer 14 is partially exposed. In this manner, non-Al-rich parts 15b are formed out of the second optical guide layer prototype 15A.

Then, as shown in FIG. 4C, an MOCVD process is performed to grow respective crystals again with the mask pattern 50 left, thereby forming Al-rich parts 15a of p-Al_{0.7}Ga_{0.3}As, second cladding layer 16 and contact layer 17. Subsequently, the mask pattern 20 is removed and then p- and n-side electrodes 18 and 19 are formed on the contact layer 17 and on the backside of the substrate 11, respectively. Thereafter, the Alrich part 15a, interposed between the non-Al-rich parts 15b, is cleaved at the center, thereby defining the facets 20 of the resonant cavity. In this manner, the semiconductor laser diode shown in FIG. 1 is completed.

Thus, according to the fabrication process of the first embodiment, the quantum well active layer 14 is not etched and most of the active layer 14 (i.e., parts of the layer 14 under the non-Al-rich parts 15b) is not exposed to the etching gas. That is to say, no etching damage is done on the active layer 14. Accordingly, the deterioration in performance of the semiconductor laser diode with time can be reduced considerably.

Next, the performance of the semiconductor laser diode according to the first embodiment will be described.

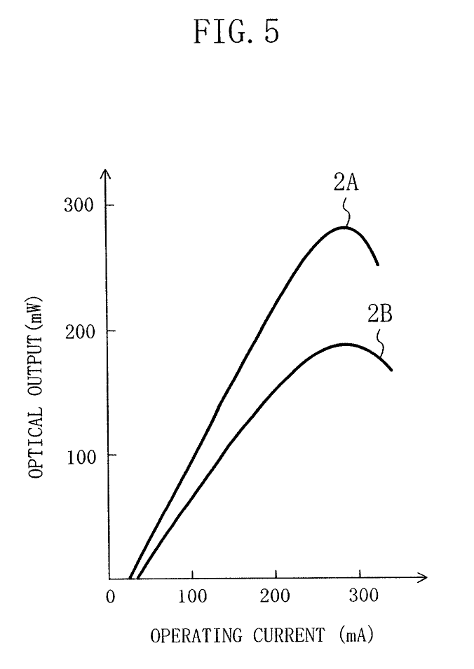

FIG. 5 illustrates the current-optical output power characteristics of semiconductor laser diodes according to the first embodiment and the first prior art example in comparison. In FIG. 5, the abscissa indicates the operating current, while the ordinate indicates the optical output power. The characteristics of the laser diodes of the first embodiment and the first prior art example are represented by the curves 2A and 2B, respectively.

As can be seen from FIG. 5, the laser diode of the first embodiment has a threshold current value smaller than that of the diode of the first prior art example. In addition, the slope efficiency and maximum optical output power of the diode of the first embodiment are both greater than those of the first prior art example. Specifically, the maximum output power of the diode of the first embodiment is 1.5 time higher than that of the diode of the first prior art example.

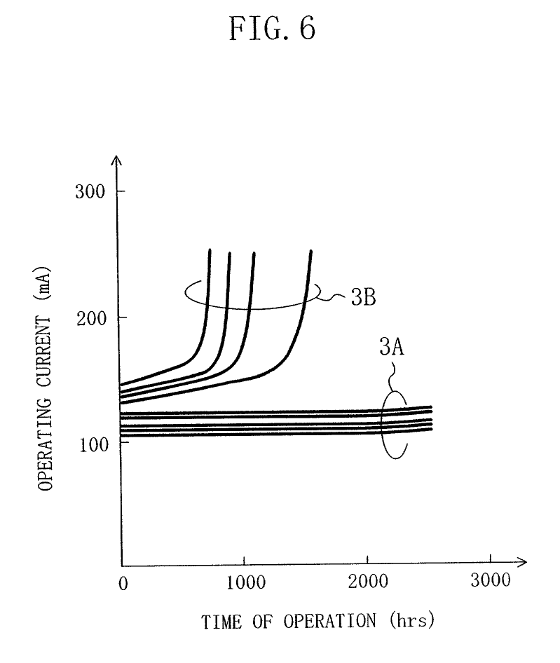

FIG. 6 illustrates results of a high-temperature continuity test that was carried out on the semiconductor laser diodes of the first embodiment and the first prior art example. In FIG. 6, the abscissa indicates the time of operation, while the ordinate indicates the operating current. In this case, these diodes were made to continuously oscillate under the conditions that the operating temperature was 60° C. and the optical output power was kept constant at 100 mW. The characteristics of the laser diodes of the first embodiment and the first prior art example are represented by the two sets 3A and 3B of curves, respectively.

As can be seen from FIG. 6, the operating current of the laser diode of the first prior art example steeply rose when the diode was operated for about 1,000 hours. In contrast, even after the laser diode of the first embodiment had been operated for more than 2,000 hours, the operating current thereof was substantially constant. Thus, it can be seen that the diode of the first embodiment can operate much more reliably than the diode of the first prior art example.

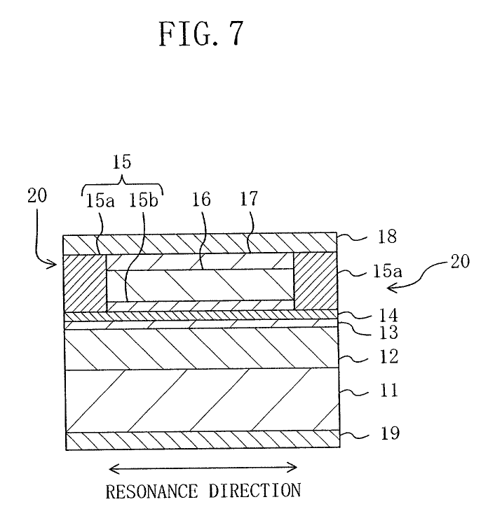

It should be noted that the same effects are attainable even if the Al-rich parts 15a of the second optical guide layer 15 are grown to the top of the epitaxial structure as shown in FIG. 7.

In the foregoing embodiment, the Al-rich parts 15a, which create the high-quantum-level regions 10 in the quantum well active layer 14, are formed on the active layer 14. Optionally, one or more semiconductor layers may be interposed between the Al-rich parts 15a and the active layer 14. In that case, the effects of this embodiment are also attainable so long as the total thickness of the additional semiconductor layers is smaller than the amplitude of the wave function of electrons or holes confined in the quantum well active layer 14.

EMBODIMENT 2

Hereinafter, a second embodiment of the present invention will be described with reference to the accompanying drawings.

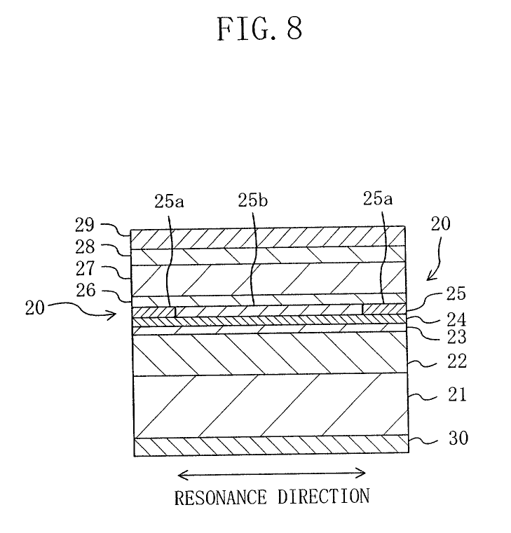

FIG. 8 illustrates a cross-sectional structure for a semiconductor laser diode according to the second embodiment. The cross section illustrated in FIG. 8 is taken in the resonance direction.

As shown in FIG. 8, an epitaxial structure is formed on a substrate 21 of n-GaAs, for example. The structure includes first cladding layer 22, first optical guide layer 23, quantum well active layer 24, barrier layer 25, second optical guide layer 26, second cladding layer 27 and contact layer 28 that have been stacked in this order. The first cladding layer 22 is made of n-Al_{0.5}Ga_{0.5}As and has a thickness of about 1.5 μm. The first optical guide layer 23 is made of undoped Al_{0.3}Ga_{0.7}As and has a thickness of about 20 nm. The active layer 24 is made of undoped GaAs and has a thickness of about 5 nm. The barrier layer 25 contains aluminum and arsenic and has a thickness of about 2 nm. The second optical guide layer 26 is made of undoped Al_{0.3}Ga_{0.7}As and has a thickness of about 20 nm. The second cladding layer 27 is made of p-Al_{0.5}Ga_{0.5}As. And the contact layer 28 is made of p-GaAs.

A p-side electrode 29 is formed on the contact layer 28 by stacking Cr, Pt and Au layers, for example, in this order thereon. On the backside of the substrate 21, i.e., on the opposite side to the p-side electrode 29, an n-side electrode 30 is formed by stacking an alloy layer containing Au, Ge and Ni, for example, and an Au layer in this order thereon.

The facets 20 of the epitaxial structure, which are located at both ends of the resonant cavity as defined in the resonance direction, are formed to be substantially vertical to the principal surface of the substrate 21 and to be parallel to each other.

The second embodiment is characterized in that part of the barrier layer 25, interposed between the quantum well active layer 24 and second optical guide layer 26, has a composition different from that of the other parts thereof. And these two types of parts with mutually different compositions are adjacent to each other in the resonance direction. Specifically, parts of the barrier layer 25, which extend from the facets 20 inward over a distance of about 10 μm each, are oxidized parts 25a made of aluminum arsenide oxide (i.e., AlₓAs_{y}O_{1-x-y}, where 0<x<1, 0<y<1 and 0<x+y<1). The other part of the barrier layer 25 interposed between these oxidized parts 25a is a non-oxidized part 25b made of aluminum arsenide (AlAs).

The barrier layer 25 includes the oxidized parts 25a near both facets 20 of the resonant cavity. Thus, the bandgap of the oxidized parts 25a is greater than that of the non-oxidized part 25b. As a result, the first quantum level (i.e., the ground-state quantum level) in parts of the active layer 24 around the facets 20 of the resonant cavity becomes higher than that in the other part of the active layer 24 under the non-oxidized part 25b. Accordingly, those parts of the active layer 24, located under the oxidized parts 25a, have their absorption coefficient decreased considerably. That is to say, the laser radiation, created in the active layer 24, is much less likely to be absorbed into the resonant cavity around the facets 20 thereof, thus suppressing the COD phenomenon. As a result, the semiconductor laser diode can have its threshold current density decreased and have its slope efficiency and maximum optical output power both increased.

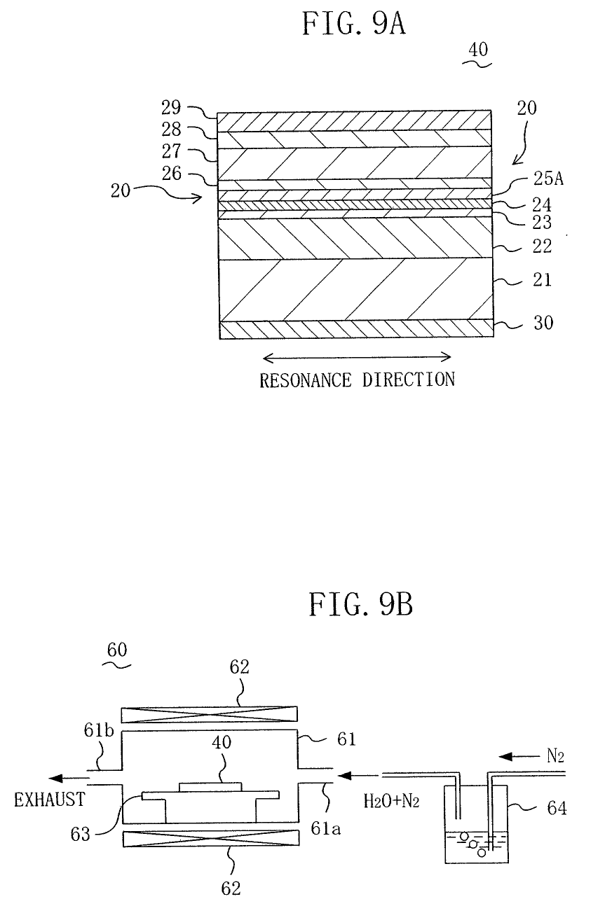

Hereinafter, a method for fabricating a semiconductor laser diode with such a structure will be described with reference to FIGS. 9A and 9B.

First, as shown in FIG. 9A, the first cladding layer 22, first optical guide layer 23, quantum well active layer 24, barrier layer prototype 25A of AlAs, second optical guide layer 26, second cladding layer 27 and contact layer 28 are formed in this order on the n-GaAs substrate 21 by an MOVPE process, for example. In this manner, an epitaxial substrate 40 is prepared. Thereafter, the p- and n-side electrodes 29 and 30 are formed on the contact layer 28 and on the backside of the substrate 21, respectively. Thereafter, the epitaxial substrate 40 is cleaved at a predetermined position, thereby defining the facets 20 of the resonant cavity.

Next, as shown in FIG. 9B, the cleaved epitaxial substrate 40 is oxidized using an electric furnace 60 within a water vapor ambient.

The electric furnace 60 includes a reaction tube 61 of quartz and a heater 62 that surrounds the tube 61. The tube 61 has gas inlet and outlet ports 61a and 61b. A substrate holder 63 is placed inside the tube 61.

Using this electric furnace 60, the oxidation process may be performed with the epitaxial substrate 40, which is held on the holder 63 and heated to about 300° C. or more, exposed to a mixture of water vapor (H₂O) and nitrogen (N₂) gas. The mixture is produced by externally blowing the nitrogen gas against the water stored in a tank 64. Also, by adjusting the heating temperature, the oxidation rate of the barrier layer prototype 25A is controllable. The pressure inside the tube 61 is atmospheric pressure.

In this manner, oxygen atoms in the state of water vapor are introduced through the facets 20 of the resonant cavity into the epitaxial substrate 40, thereby selectively oxidizing the barrier layer prototype 25A. As a result, the oxidized parts 25a of aluminum arsenide oxide are formed at the edges of the barrier layer prototype 25A.

As can be seen, the AlAs barrier layer prototype 25A, formed on the quantum well active layer 24, reacts with oxygen very easily. Thus, the edges of the barrier layer prototype 25A can be oxidized selectively almost without oxidizing the quantum well active layer 24. As a result, the oxidized parts 25a can be formed at the edges of the barrier layer prototype 25A just as intended.

Hereinafter, the performance of the semiconductor laser diode according to the second embodiment will be described.

First, the difference in bandgap between the oxidized and non-oxidized parts 25a and 25b as identified by a photoluminescence spectroscopy will be described.

The peak wavelengths of photoluminescence emission spectra of the AlₓAs_{y}O_{1-x-y} oxidized parts 25a and AlAs non-oxidized part 25b measured about 760 nm and 797 nm, respectively, according to the results of experiments carried by the present inventors. Thus, it can be seen that the peak wavelength of the oxidized parts 25a shifted (or decreased) from that of the non-oxidized part 25b and that the oxidized parts 25a should have a bandgap greater than that of the non-oxidized part 25b.

Next, the current-optical output power characteristic of the semiconductor laser diode of the second embodiment will be described.

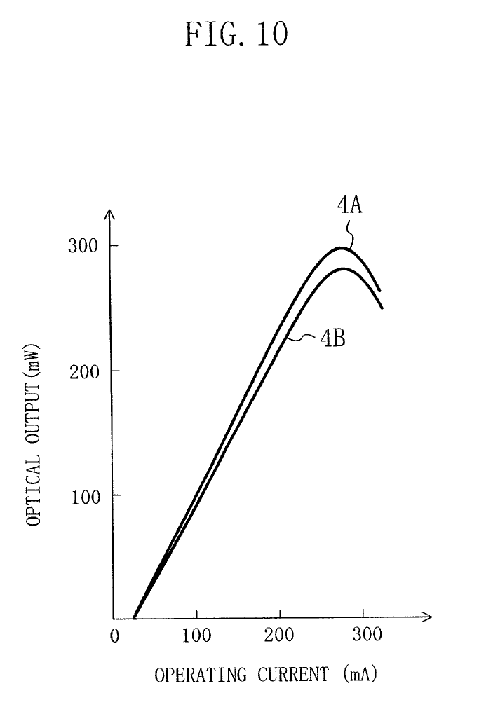

FIG. 10 illustrates the current-optical output power characteristics of semiconductor laser diodes according to the first and second embodiments in comparison. In FIG. 10, the abscissa indicates the operating current, while the ordinate indicates the optical output power. The characteristics of the laser diodes of the first and second embodiments are represented by the curves 4B and 4A, respectively.

As can be seen from FIG. 10, the laser diode of the second embodiment has a threshold current value slightly smaller than that of the diode of the first embodiment. In addition, the slope efficiency and maximum optical output power of the diode of the second embodiment are both greater than those of the first embodiment. This is because AlₓAs_{y}O_{1-x-y} for the oxidized parts 25a has so high insulation properties that the amount of idle current flowing through the oxidized parts 25a is much smaller.

In the second embodiment, the quantum well active layer 24 is made of GaAs. However, the same effects are attainable even if the active layer 24 is made of AlGaAs with a small Al mole fraction. Where Al is contained, the Al mole fraction should be about 0.3 or less, because the luminous efficacy can be particularly increased in that case.

The thickness of the barrier layer 25 is preferably from 0.5 nm through 20 nm. The reason is as follows. If the thickness of the barrier layer 25 is 0.5 nm or more, then part of the active layer 24 with a thickness representing the wave function of electrons and holes in the active layer 24 does not expand deeper into the second optical guide layer 26. As a result, the rise in quantum energy level of the active layer 24, which has been caused due to the increased bandgap of the barrier layer 25, is promoted.

On the other hand, if the thickness of the barrier layer 25 is 20 nm or less, then a good number of carriers are injected from the second optical guide layer 26 into the active layer 24. As a result, the operating voltage of the semiconductor laser diode decreases.

Also, the barrier layer 25, which is interposed between the active layer 24 and the p-type second cladding layer 27, may be undoped but is preferably doped with a p-type dopant. In that case, holes can be injected into the active layer 24 even more efficiently.

In the second embodiment, the AlAs barrier layer 25 is formed between the active layer 24 and the second optical guide layer 26. Alternatively, the AlAs barrier layer may be provided between the active layer 24 and the first optical guide layer 23. As another alternative, the AlAs barrier layers may be formed under and over the active layer 24. Where the barrier layer is formed on the n-type first optical guide layer 23, the barrier layer may be undoped but is preferably doped with an n-type dopant. This is because electrons can be injected into the active layer 24 even more efficiently in that case.

Furthermore, in the second embodiment, the oxidized parts 25a, which create the high-quantum-level regions in the quantum well active layer 24, are defined on the active layer 24. Optionally, one or more semiconductor layers may be interposed between the oxidized parts 25a and the active layer 24. In that case, the effects of this embodiment are also attainable so long as the total thickness of the additional semiconductor layers is smaller than the amplitude of the wave function of electrons or holes confined in the quantum well active layer 24.

EMBODIMENT 3

Hereinafter, a third embodiment of the present invention will be described with reference to the accompanying drawings.

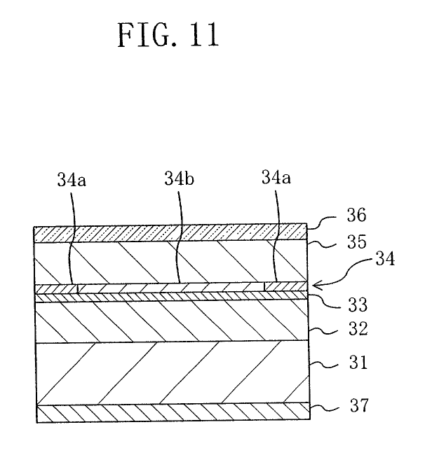

FIG. 11 illustrates a cross-sectional structure for a light-emitting diode according to a third embodiment of the present invention.

As shown in FIG. 11, first cladding layer 32, quantum well active layer 33, barrier layer 34 and second cladding layer 35 are stacked in this order on a substrate 31 of n-GaAs. The first cladding layer 32 is made of n-AlGaInP and has a thickness of about 1 μm. The active layer 33 is made of undoped InGaP and has a thickness of about 5 nm. The barrier layer 34 contains AlInP and has a thickness of about 2 nm. The second cladding layer 35 is made of p-AlGaInP.

A p-side electrode 36, which is transparent to the radiation emitted, is formed on the second cladding layer 35. On the backside of the substrate 31, i.e., on the opposite side to the p-side electrode 36, an n-side electrode 37 is formed by stacking an alloy layer containing Au, Ge and Ni, for example, and an Au layer in this order thereon.

The third embodiment is characterized in that part of the barrier layer 34, interposed between the quantum well active layer 33 and second cladding layer 35, has a composition different from that of the other parts thereof. And these two types of parts with mutually different compositions are adjacent to each other within a plane. Specifically, parts of the barrier layer 34, which extend from the side faces inward over a distance of about 10 μm each, are oxidized parts 34a made of a compound of AlInP and oxygen. The other part of the barrier layer 34 interposed between these oxidized parts 34a is a non-oxidized part 34b made of AlInP.

The barrier layer 34 includes the oxidized parts 34a around the side faces thereof. Thus, the bandgap of the oxidized parts 34a is greater than that of the non-oxidized part 34b. As a result, the amount of the operating current, flowing into the oxidized parts 34a can be reduced. That is to say, it is possible to reduce the amount of current injected into those parts of the active layer 33 around the side faces thereof, where centers of non-radiative recombination, not contributing to the emission, exist in great numbers. Accordingly, the light-emitting diode can have its luminous efficacy increased.

The light-emitting diode of the third embodiment may be fabricated as in the second embodiment. Specifically, first, the respective semiconductor layers are grown epitaxially. Next, the p- and n-side electrodes 36 and 37 are formed. Then, the substrate is cleaved to a predetermined size. And then the cleaved end faces are annealed and oxidized within a water vapor ambient. By performing this oxidation process, the oxidized parts 34a, extending from the cleaved end faces of the barrier layer 34 inward, are formed out of a compound of AlInP and oxygen.

In this process step, AlInP, which reacts with oxygen very easily, is oxidized selectively. Accordingly, the active layer 33 of InGaP is hardly oxidized and only those parts of the barrier layer 34 around the end faces can be oxidized selectively. As a result, the quantum well active layer 33 can exhibit good emission characteristics. In this case, the active layer 33 may be made of GaP, not InGaP.

It should be noted that the barrier layer 34 may be oxidized selectively by a mixture of oxygen plasma and hydrogen instead of water vapor.

Hereinafter, the performance of the light-emitting diode of the third embodiment will be described.

First, the difference in bandgap between the oxidized and non-oxidized parts 34a and 34b as identified by a photoluminescence spectroscopy will be described.

The peak wavelengths of photoluminescence emission spectra of the oxidized parts 34a and non-oxidized part 34b measured about 600 nm and 630 nm, respectively, according to the results of experiments carried by the present inventors. Thus, it can be seen that the peak wavelength of the oxidized parts 34a shifted (or decreased) from that of the non-oxidized part 34b and that the oxidized parts 34a should have a bandgap greater than that of the non-oxidized part 34b.

Next, the current-emission intensity characteristic of the light-emitting diode of the third embodiment will be described.

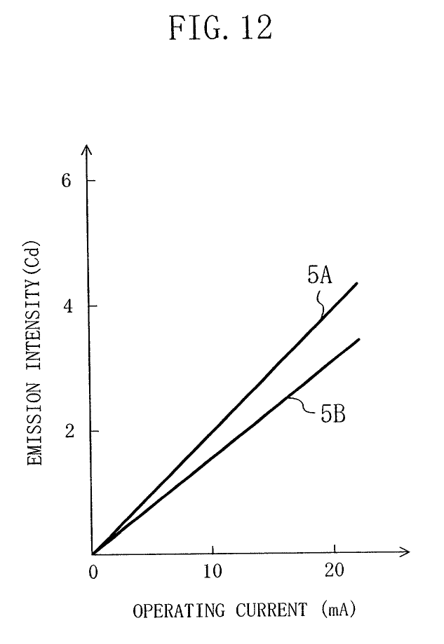

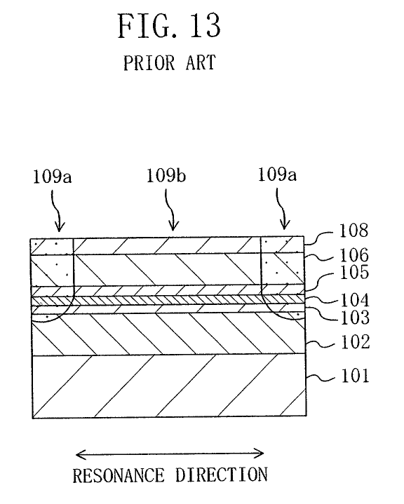

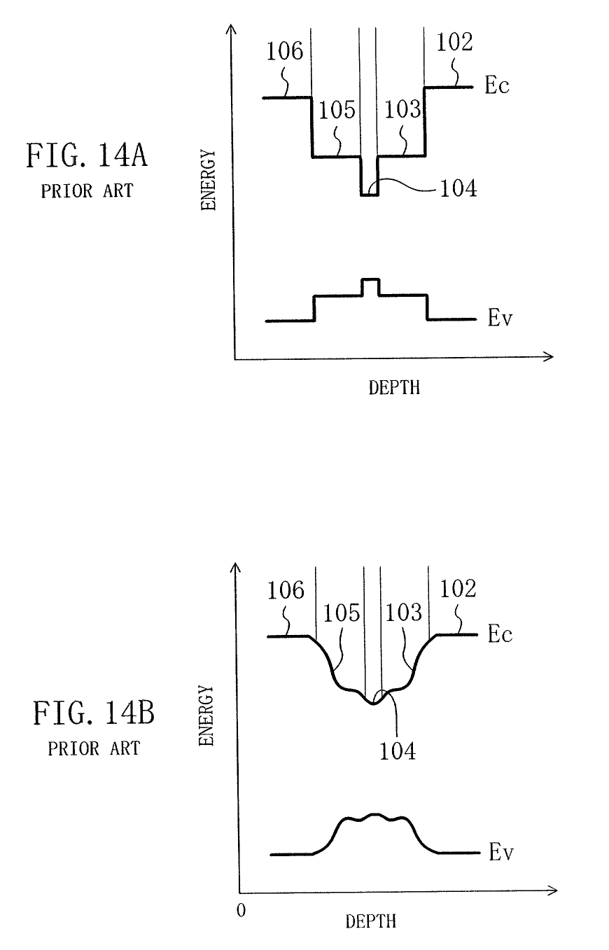

FIG. 12 illustrates the current-emission intensity characteristics of a light-emitting diode according to the third embodiment with the oxidized parts 34a and a known light-emitting diode with no oxidized parts 34a in comparison. In FIG. 10, the abscissa indicates the operating current, while the ordinate indicates the emission intensity. The characteristics of the light-emitting diodes of the third embodiment and the prior art are represented by the curves 5A and 5B, respectively.

As can be seen from FIG. 12, the light-emitting diode of the third embodiment has an emission intensity greater than that of the known diode by about 10%. This is because interfacial levels are created around the cleaved end faces of the active layer 33 due to the exposure of the faces to the air. As a result, centers of non-radiative recombination are formed around the end faces of the active layer 33 so that the luminous efficacy decreases near the facets.

The light-emitting diode of the third embodiment includes the oxidized parts 34a with a bandgap greater than that of the inner part 34b around the side edges of the barrier layer 34. Thus, a larger part of the current injected flows through the non-oxidized part 34b than the oxidized parts 34a located around the side edges. That is to say, a greater amount of current flows through the non-oxidized part 34b exhibiting a higher luminous efficacy. As a result, the light-emitting diode can have its luminous efficacy increased.

In the third embodiment, the AlInP barrier layer 34 is formed between the active layer 33 and the second cladding layer 35. Alternatively, the AlInP barrier layer may be provided only between the active layer 33 and the first cladding layer 32. As another alternative, the InGaP barrier layers may be formed under and over the active layer 33. Where the barrier layer is formed on the n-type first cladding layer 32, the barrier layer may be undoped but is preferably doped with an n-type dopant. This is because electrons can be injected into the active layer 33 even more efficiently in that case.

Furthermore, in the third embodiment, the oxidized parts 34a, which create the high-quantum-level regions in the quantum well active layer 33, are defined on the active layer 33. Optionally, one or more semiconductor layers may be interposed between the oxidized parts 34a and the active layer 33. In that case, the effects of this embodiment are also attainable so long as the total thickness of the additional semiconductor layers is smaller than the amplitude of the wave function of electrons or holes confined in the active layer 33.

In the foregoing embodiments, the active layer for creating radiation to be emitted has a single quantum well structure. Alternatively, the active layer may have a multiquantum well (MQW) structure having multiple quantum wells.

If the MQW structure is applied to the first embodiment, each of the barrier layers in the MQW structure should be thin enough to allow electrons to be combined between the quantum wells. That is to say, the MQW structure is preferably of a combination type.

On the other hand, if the MQW structure is applied to the second or third embodiment, the bandgap at the edges of a barrier layer, adjacent to each quantum well layer, should be greater than the inner part of the barrier layer.

Also, in the foregoing embodiments, the Al-rich parts or oxidized parts, which create the high-quantum-level regions, are formed at both ends. Alternatively, only one such part may be provided at either end.

Furthermore, in the foregoing embodiments, the semiconductor layers are made of AlGaAs or AlGaInP. However, these layers may also be made of a Group III nitride semiconductor that can emit radiation at an even shorter wavelength, i.e., BₓAl_{y}Ga_{1-x-y-z}In_{z}N, where 0≦x≦1, 0≦y≦1, 0≦z≦1 and 0≦x+y+z≦1.

What is claimed is:

1. A semiconductor light emitter comprising:
a first semiconductor layer formed over a substrate;
a second semiconductor layer formed over the first layer; and
a third semiconductor layer formed over the second layer,
wherein bandgaps of the first and third layers are greater than a bandgap of the second layer, and
wherein a high-quantum-level region is defined around an edge of the second layer, the first quantum level being higher in the high-quantum-level region than in the other regions of the second layer.

2. The emitter of claim 1, wherein parts of the first or third layer, which are located near the edges of the second layer, have a bandgap greater than the other part of the first or third layer.

3. The emitter of claim 1, wherein the first layer has a pair of facets that extend substantially vertically to the principal surface of the substrate and that face each other, and
wherein at least one of these facets is located in the high-quantum-level region.

4. The emitter of claim 1, wherein each said high-quantum-level region is defined to extend from an associated facet of the second layer inward over a predetermined distance.

5. The emitter of claim 1, wherein the first or third layer has a thickness of 0.5 nm through 20 nm.

6. The emitter of claim 1, wherein the first or third layer is made of a semiconductor that reacts with oxygen atoms more easily than the second layer does, and
wherein oxygen atoms have been introduced into edges of the first or third layer to a level higher than the other part of the first or third layer so that a bandgap at the edges of the first or third layer is greater than a bandgap in the other part of the first or third layer.

7. The emitter of claim 1, wherein the first and third layers are made of AlGaAs, and
wherein the second layer is made of: AlGaAs that has an Al mole fraction smaller than that of AlGaAs for the first and third layers; InGaAs; or GaAs.

8. The emitter of claim 7, wherein the Al mole fraction in the second layer is 0.3 or less.

9. The emitter of claim 1, wherein the first and third layers are made of AlGaInP, and
wherein the second layer is made of: AlGaInP that has an Al mole fraction smaller than that of AlGaInP for the first and third layers; InGaP; or GaAs.

10. The emitter of claim 9, wherein the Al mole fraction in the second layer is 0.3 or less.

11. The emitter of claim 1, wherein the first and third layers are made of BₓAl_{y}Ga_{1-x-y-z}In_{z}N, where 0≦x≦1, 0≦y≦1, 0≦z≦1 and 0≦x+y+z≦1, and
wherein the second layer is made of: BₓAl_{y}Ga_{1-x-y-z}In_{z}N, where 0≦x≦1, 0≦z≦1 and 0≦x+y+z≦1 and which has an Al mole fraction smaller than that of BₓAl_{y}Ga_{1-x-y-z}In_{z}N for the first and third layers; InGaN; or GaN.

12. The emitter of claim 1, wherein the second layer comprises a quantum well layer.

13. A semiconductor light emitter comprising:
a first semiconductor layer formed over a substrate;
a second semiconductor layer formed over the first layer; and
a third semiconductor layer formed over the second layer,
wherein the first or third layer has a bandgap greater than a bandgap of the second layer and is made of a semiconductor that reacts with oxygen atoms more easily than the second layer does, and
wherein oxygen atoms have been introduced into edges of the first or third layer to a level higher than the other part of the first or third layer so that a bandgap at the edges of the first or third layer is greater than a bandgap in the other part of the first or third layer.

14. The emitter of claim 13, wherein the second layer comprises a quantum well layer.

15. A method for fabricating a semiconductor light emitter, comprising the steps of:
a) stacking first, second and third semiconductor layers in this order over a substrate to obtain a multilayer structure including the first, second and third layers; and
b) exposing at least one side face of the multilayer structure to an ambient containing oxygen atoms, thereby oxidizing a side face of the first or second layer.

16. The method of claim 15, wherein the first and third layers have a bandgap greater than that of the second layer.

17. The method of claim 15, wherein the first or third layer is made of a semiconductor that reacts with oxygen atoms more easily than the second layer does.

18. The method of claim 15, wherein the step a) comprises the step of forming a quantum well layer in the second layer.

19. The method of claim 15, wherein the step b) comprises an annealing process in which water vapor is used as the ambient.
